(19) United States
(12) Patent Application Publication
(10) Pub. No.: US 2017/0237918 A1
(43) Pub. Date: Aug. 17, 2017

(54) LIGHT FIELD IMAGING WITH TRANSPARENT PHOTODETECTORS

(71) Applicant: THE REGENTS OF THE UNIVERSITY OF MICHIGAN, Ann Arbor, MI (US)

(72) Inventors: Theodore B. NORRIS, Dexter, MI (US); Zhaohui ZHONG, Ann Arbor, MI (US); Jeffrey A. FESSLER, Ann Arbor, MI (US); Che-Hung LIU, Folsom, CA (US); You-Chia CHANG, New York, NY (US)

(21) Appl. No.: 15/430,043

(22) Filed: Feb. 10, 2017

Related U.S. Application Data
(60) Provisional application No. 62/294,386, filed on Feb. 12, 2016.

(51) Int. Cl. H04N 5/369; H01L 27/146; G06T 7/557

(52) U.S. Cl. CPC H04N 5/369; G06T 7/557; H01L 27/14627; G06T 2207/10052; G06T 2207/20056; G02B 5/003

(57) ABSTRACT

A light field imaging system with transparent photodetectors is presented. The light field imaging system includes: a stack of two or more detector planes, an imaging optic, and an image processor. The detector planes include one or more transparent photodetectors, such that transparent photodetectors have transparency greater than fifty percent (at one or more wavelengths) while simultaneously exhibiting responsivity greater than one amp per watt. The imaging optic is configured to receive light rays from a scene and refract the light rays towards the stack of two or more detector planes, such that the refracted light rays pass through the transparent detector planes and the refracted light rays are focused within the stack of detector planes. The image processor reconstruct a light field for the scene (at one of more wavelengths) using the light intensity distribution measured by each of the photodetectors.

### CROSS-REFERENCE TO RELATED APPLICATIONS

This application claims the benefit of U.S. Provisional Application No. 62/294,386 filed on Feb. 12, 2016. The entire disclosure of the above application is incorporated herein by reference.

### GOVERNMENT CLAUSE

This invention was made with government support under Grant Nos. ECCS0125446 and DMR1120923 awarded by the U.S. National Science Foundation. The Government has certain rights in this invention.

### FIELD

The present disclosure relates to light field imaging with transparent photodetectors.

### BACKGROUND

The optical sensors in the vast majority of today's imaging devices are flat (two-dimensional) devices that record the intensity of the impinging light for three particular colors (red, green, and blue) at each pixel on the sensor. Because light is detected in only a single plane, all information about the direction of the light rays is lost. As a result, the recorded images are 2D projections of the actual object in real space, with a finite depth of field (i.e., only a limited region of the object space is actually in precise focus). The ultimate imaging system would produce a complete representation of the 3D scene, with an infinite depth of field. For any given wavelength, the light rays emanating from 3D objects in a scene contain five dimensions (5D) of information, namely the intensity at each location in space and the angular direction (θ, φ) of propagation. An imaging system will collect these light rays and propagate them to an optical sensor array. At any given plane in the system, the light distribution at a given wavelength (color), may be described via a 4D function, corresponding to the intensity of the light at each transverse position (x,y) and the direction of propagation described by angles (u,v). Such a 4D representation of the propagation though the imaging system is known as the light field; knowledge of the complete light field enables computational reconstruction of objects in the image space, for example digital refocusing to different focal planes, novel view rendering, depth estimation, and synthetic aperture photography. Indeed, the co-development of novel optical systems and computational photography is opening up exciting new frontiers in imaging science, well beyond the traditional camera and its biological inspiration, the eye.

Various schemes for light field imaging have been proposed and demonstrated. For example, one may employ an array of microlenses at the focal plane of the imaging lens, in conjunction with a 2D detector array, to obtain the angular information necessary to reconstruct the light field. The first prototype utilizing this approach was implemented in 2005, and imaging devices of this type are referred to as plenoptic cameras. This approach, however, has an inherent tradeoff of spatial resolution for angular resolution. Schemes incorporating programmable apertures, focal sweep cameras and other mask-based designs attempt to solve the low-resolution problem, but they either suffer from signal-to-noise limitations or require multiple images to be acquired and therefore are not suitable for recording dynamic scenes. Implementing a full-sensor-resolution, high SNR and real-time light field imaging system remains a challenging problem.

This section provides background information related to the present disclosure which is not necessarily prior art.

### SUMMARY

This section provides a general summary of the disclosure, and is not a comprehensive disclosure of its full scope or all of its features.

A light field imaging system with transparent photodetectors is presented. The light field imaging system includes: a stack of two or more detector planes, an imaging optic, and an image processor. Each of the two or more detector planes is arranged in a different geometric plane and the geometric planes are substantially parallel with each other. The detector planes include one or more transparent photodetectors, such that transparent photodetectors have transparency greater than fifty percent (at one or more wavelengths) while simultaneously exhibiting responsivity greater than one amp per watt. The imaging optic is configured to receive light rays from a scene and refract the light rays towards the stack of two or more detector planes, such that the refracted light rays pass through the transparent detector planes and the refracted light rays are focused within the stack of detector planes. The image processor is in data communication with each of the photodetectors in the stack of two or more detector planes and operates to reconstruct a light field for the scene (at one of more wavelengths) using the light intensity distribution measured by each of the photodetectors.

In one embodiment, each detector plane includes an array of photodetectors and each photodetector in a given array of photodetectors aligns with a corresponding photodetector in each of the other arrays of photodetectors.

In one aspect, a method is provided for reconstructing a light field from data recorded by a light field imaging system. The method includes: determining a transformation matrix that relates a light field from a given scene to predicted light intensity distribution as would be measured by a stack of detector planes in the light field imaging system; measuring the light intensity distribution of light propagating from an unknown scene at each detector plane in the stack of detector planes; and reconstructing a light field for the unknown scene using the transformation matrix and the measured light intensity from the unknown scene.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a diagram of a focal stack light field imaging system;

FIGS. 2A and 2B are a perspective view and a cross-sectional side view of an example embodiment of a transparent heterojunction photodetector, respectively;

FIGS. 2C and 2D are a perspective view and a cross-sectional side view of a second example embodiment of a transparent heterojunction photodetector, respectively;

FIG. 3 is a diagram of a detector plane showing the interconnections between photodetectors;

FIG. 4 is a diagram of an experimental scheme for demonstrating the light field imaging system;

FIG. 5 is a graph showing the focusing point of the two detector planes in the experimental setup;

FIG. 6 is a flowchart depicting a method for reconstructing a light field from data recorded by the light field imaging system;

FIG. 7 is a diagram of a two-dimensional light field space;

FIG. 8 is a diagram illustrating a light field imaging system with unequal spacing between detector planes;

FIG. 9 is a diagram depicting a technique for determining placement of detector planes in a light field imaging system;

FIGS. 10A-10C are images of two patterned disks obtained under different reconstruction scenarios;

FIG. 11 are digitally refocused images of the two patterned disks rendered from the reconstructed light field; and

FIGS. 12A and 12B are graphs of the squared error between the true light field and the reconstructed light field as a function of iteration of the construction algorithm for ordinary least squares and regularized least squares, respectively.

Corresponding reference numerals indicate corresponding parts throughout the several views of the drawings.

### DETAILED DESCRIPTION

Example embodiments will now be described more fully with reference to the accompanying drawings.

The key technology at the center of the proposed light field imaging system is a transparent photodetector. Present imaging systems employ a single optical sensor (photodetector array), usually at the focus of a lens system. Being made of silicon or similar material, the sensor is opaque, resulting in the loss of directional information on the light ray. If one could make highly sensitive but nearly transparent sensors, then multiple sensor arrays could be stacked along the path of the light rays, enabling directional information to be retained, and thus enabling computational reconstruction of the light field from data recorded by a single exposure. Recent breakthroughs in optoelectronic materials enable this new imaging paradigm to be realized. In particular, the discovery of graphene has sparked interest in a whole class of atomic layer crystals including graphene, hexagonal boron nitride, molybdenum disulphide and other transition metal dichalcogenides (TMDCs). Unlike conventional semiconductors, their ultimate thinness (one or few atomic layers), make them nearly transparent across the electromagnetic spectrum. Despite this, the strong light-matter interaction in these 2D atomic crystals makes them sensitive light sensors at the same time. It may seem a paradox that a sensitive detector could also be nearly transparent, but this combination of properties is a special property of these 2D electronic materials. For simplicity, the remaining description focuses on a single wavelength but the extension of the teachings in this disclosure to color images is readily understood by those knowledgeable in the art.

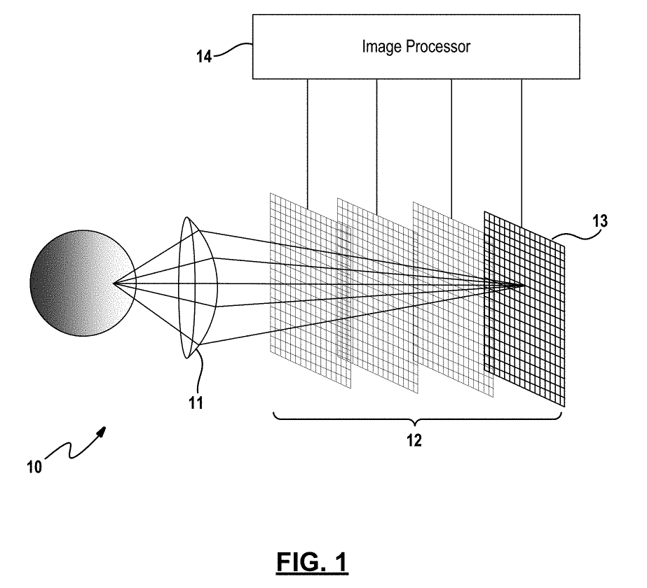

FIG. 1 depicts an example light field imaging system 10. The light field imaging system 10 is comprised of an imaging optic 11, a stack of two of more detector planes 12, and an image processor 14. Each of the detector planes is arranged in a different geometric plane and the geometric planes are parallel with each other. The detector planes 12 are transparent although the final detector plane 13 may be opaque in some embodiments. It is envisioned that other optical components (e.g., a coded aperture) may be needed to implement the overall operation of the light field imaging system.

The imaging optic 11 is configured to receive light rays from a scene and refract the light rays towards the stack of detector planes 12, such that the refracted light rays pass through the detector planes 12. The refracted light rays are focused within the stack of detector planes 12. In one embodiment, the imaging optic 11 focuses the refracted light rays onto one of the detector planes. In other embodiments, the imaging optic 11 may focus the refracted light rays in between two of the detector planes 12. In the example embodiment, the imaging optic 11 is implemented by an objective lens and the light is focused onto the final detector plane 13. Other types of imaging optics are contemplated including but not limited to camera lens, metalens, microscope lens and zoom lens.

The detector planes 13 include one or more transparent photodetectors. In an example embodiment, the transparent photodetectors include a light absorbing layer and a substrate, where the light absorbing layer is comprised of a two-dimensional material and the substrate is comprised of a transparent material. As a result, the transparent photodetectors have transparency greater than fifty percent (and preferably >85%) while simultaneously exhibiting responsivity greater than one amp per watt (and preferably >100 amps per watt). Example constructs for transparent photodetectors are further described below. Examples of other suitable photodetectors are described by Seunghyun Lee, Kyunghoon Lee, Chang-Hua Liu and Zhaohui Zhong in “Homogeneous bilayer graphene film based flexible transparent conductor” Nanoscale 4, 639 (2012); by Seunghyun Lee, Kyunghoon Lee, Chang-Hua Liu, Girish S. Kulkarni and Zhaohui Zhong, “Flexible and transparent all-graphene circuits for quaternary digital modulations” Nature Communications 3, 1018 (2012); and by Chang-Hua Liu, You-Chia Chang, Theodore B. Norris and Zhaohui Zhong, “Graphene photodetectors with ultra-broadband and high responsivity at room temperature” Nature Nanotechnology 9, 273-278 (2014). Each of these article are incorporated in their entirety herein by reference.

In the example embodiment, each detector plane 12 includes an array of photodetectors. In some embodiments, each photodetector in a given array of photodetectors aligns with a corresponding photodetector in each of the other arrays of photodetectors. In other embodiments, photodetectors across different arrays do not necessarily align with each other. In any case, the light field imaging system records information related to the direction of propagation because rays are incident upon photodetectors across the stack of detector planes.

In operation, a bundle of light rays emitted from an object point are collected by the imaging optic 11. The imaging optic 11 refracts the light rays towards the stack of detector planes 12, such that the refracted light rays pass through at least one of the detector planes and are focused at some point within the stack of detector planes. Some of the light is absorbed by photodetectors in each of the intermediate detector planes. The sensors must absorb some of the light to obtain the intensity distribution in each (x,y) plane, but pass sufficient light that several detector planes can be positioned in front of the final detector plane 13.

The image processor 14 is in data communication with each of the photodetectors in the stack of two or more photodetectors and is configured to receive light intensity measured by each of the photodetectors. The image processor 14 in turn reconstructs a light field for the scene using the light intensity measured by each of the photodetectors. An example method for reconstructing the light field is further described below. The image processor may be specially constructed for the required purposes, or it may comprise a general-purpose computer selectively activated or reconfigured by a computer program stored on a computer readable medium that can be accessed by the computer. Such a computer program may be stored in a tangible computer readable storage medium, such as, but is not limited to, any type of disk including optical disks, CD-ROMs, magnetic-optical disks, read-only memories (ROMs), random access memories (RAMs), EPROMs, EEPROMs, magnetic or optical cards, application specific integrated circuits (ASICs), or any type of media suitable for storing electronic instructions, and each coupled to a computer system bus. Furthermore, the computers referred to in the specification may include a single processor or may be architectures employing multiple processor designs for increased computing capability.

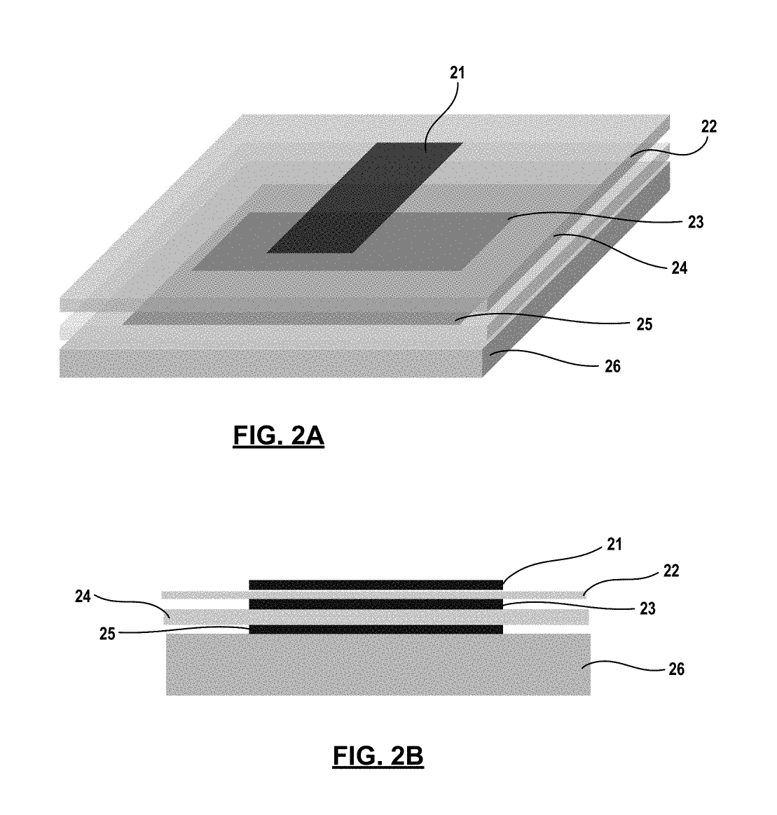

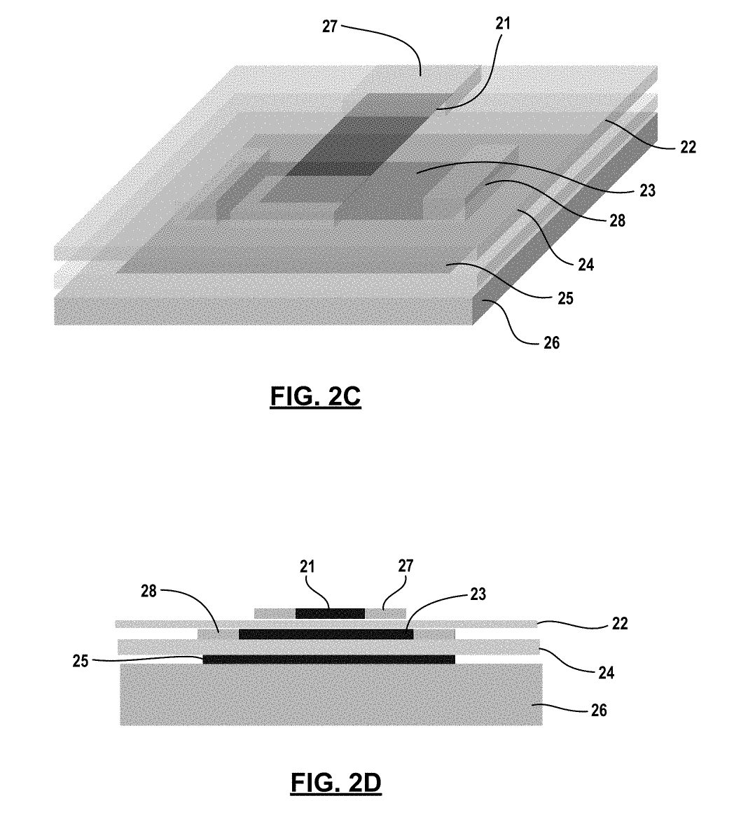

FIGS. 2A and 2B depict an example embodiment of a transparent heterojunction photodetector 20 suitable for use in the light field imaging system 10. The photodetector 20 is comprised generally of a light absorbing layer 21 disposed on a bottom-gated field effect transistor and supported by a transparent substrate 26. In the example embodiment, graphene forms the light absorbing layer 21, the channel layer 23 of the FET and the bottom gate layer 25. The graphene may be grown by chemical vapor deposition on copper foil and then transferred onto the substrate using conventional layer transfer processes, and patterned using conventional photolithography processes. The light absorbing layer 21 is separated from the channel layer 23 by a tunnel barrier layer 22. In the example embodiment, the tunnel barrier 22 is formed by a thin layer (e.g., 6 nm) of tantalum pentoxide deposited for example by RF sputtering. The channel layer 23 is separated from the bottom gate layer 25 by another barrier layer 24. In the example embodiment, the second barrier layer 24 is a dielectric material, such as aluminum oxide (e.g., 40 nm) deposited, for example with an atomic layer deposition technique. Different dielectrics are preferably deposited between the graphene layers in order to make the high performance bottom-gated FET with double layer graphene heterojunction utilize the photo-gating effect for high responsivity photo detection. Further details regarding the working principle for the heterojunction photodetector may be found in U.S. Patent Publication No. 2004/0264275 which is incorporated in its entirety by reference.

FIGS. 2C and 2D depict a second example embodiment of a transparent heterojunction photodetector 20′ which includes metal contacts. Likewise, the photodetector 20′ is comprised generally of a light absorbing layer 21 disposed on a bottom-gated field effect transistor and supported by a transparent substrate 26. In this case, metal contacts 27 are formed on longitudinal ends of the light absorbing layer 21 as well as metal contacts 28 are formed on longitudinal ends of the channel layer 23. In the example embodiment, the metal contacts are formed by gold using a metal lift-off process. Except with respect to the differences discussed herein, the photodetector 20′ may be substantially the same as the photodetector 20 described above. While the exemplary embodiments of the photodetectors have been described above with specific materials having specific values and arranged in a specific configuration, it will be appreciated that these photodetectors may be constructed with many different materials, configurations, and/or values as necessary or desired for a particular application. For example, graphene may be replaced with different two-dimensional materials including but not limited to hexagonal boron nitride, molybdenum disulphide and other transition metal dichalcogenides. The above configurations, materials and values are presented only to describe one particular embodiment that has proven effective and should be viewed as illustrating, rather than limiting, the present disclosure.

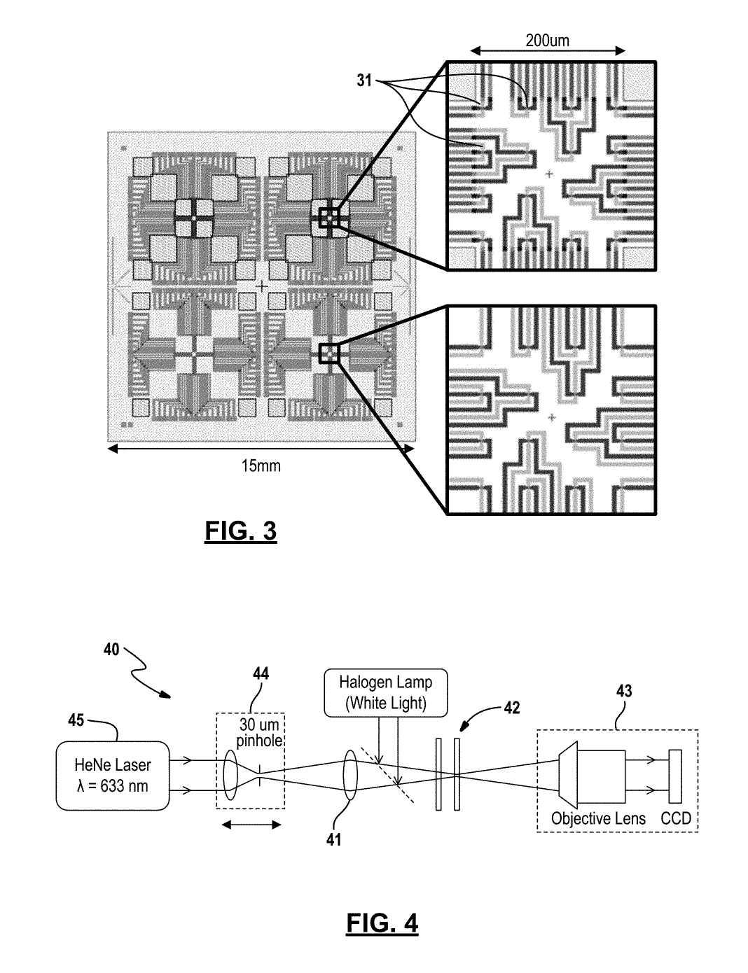

To form a detector plane, the photodetectors are arranged in an array on a transparent substrate. FIG. 3 illustrates how individual photodetectors can be interconnected. The enlarged area to the right and on top depicts a 4×4 array of photodetectors, where a single pixel is formed at each crossing indicated at 31. Similarly, the enlarged area to the right and on the bottom depicts a 4×4 array of photodetectors, where a single pixel is formed at each crossing. On the top, metal contacts are shown along the edges of the array; whereas, on the bottom, the contacts are formed from graphene and thus form an entirely transparent array of photodetectors.

FIG. 4 illustrates an experimental scheme for demonstrating the light field imaging system 40. For this demonstration, the light field imaging system 40 includes a 50 mm focal length front imaging lens 41 and two transparent graphene detectors 42 that are 2 mm apart. Behind the focal stack, a microscope 43 provides separate confirmation that the test object is perfectly imaged at the center of each graphene detector pixel. The test object is a point source 44 formed by illuminating a 200 μm pinhole with the focused 632 nm HeNe laser 45. The point source 44, the center of the imaging lens 41, the two single-pixel detectors 42, and the optical axis of the microscope 43 are well aligned on the same optical axis (referred to as the z axis).

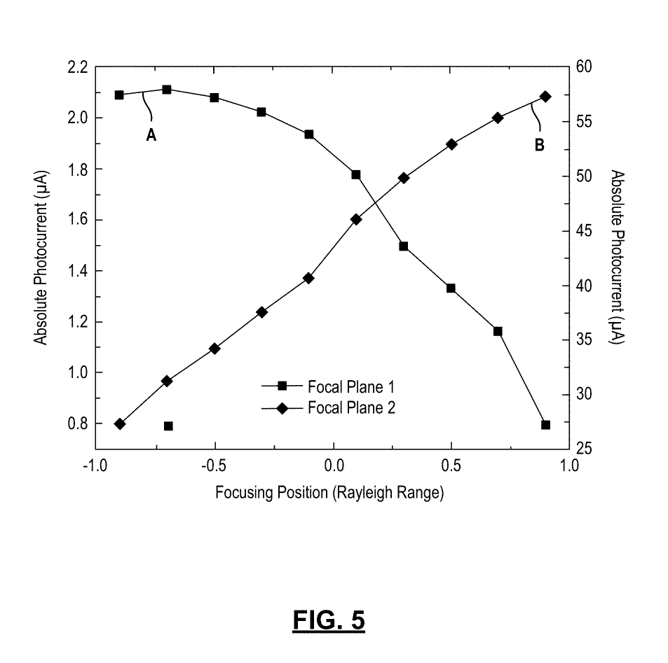

When the point source is very far from the imaging lens, the real image is completely out of focus on both of the front and the back graphene detector sheets. The point source is then moved towards the imaging lens with a linear stage. At some point, the real image of the point source will be perfectly focused on the front detector sheet while staying out of focus on the back detector sheet. Referring to FIG. 5, the current signal of the front detector reaches its maximum, as it is proportional to the optical intensity illuminated. This corresponds to the point A in FIG. 5. As we continue to move the point source toward the imaging lens, the intensity of the real image decreases on the front detector sheet and increases on the back detector. At some point, the point source is perfectly imaged on the back detector while staying out of focus on the front detector, which corresponds to the point B in FIG. 5. The curves in FIG. 5 demonstrate optical ranging or sectioning; with knowledge of the lens focal length and sensor positions, the longitudinal position of the object can be determined. In the figure, the object position is normalized to the Rayleigh range of the imaging system. In principle, high axial resolution can be obtained by imaging with a short focal length lens, e.g., a microscope objective. The axial resolution will be determined simply by the Rayleigh range/depth of field of the optic used in the imaging system, as it is in a traditional confocal microscope. Knowledge of the intensity profile along the z axis one can extract the depth information of the scene from the data.

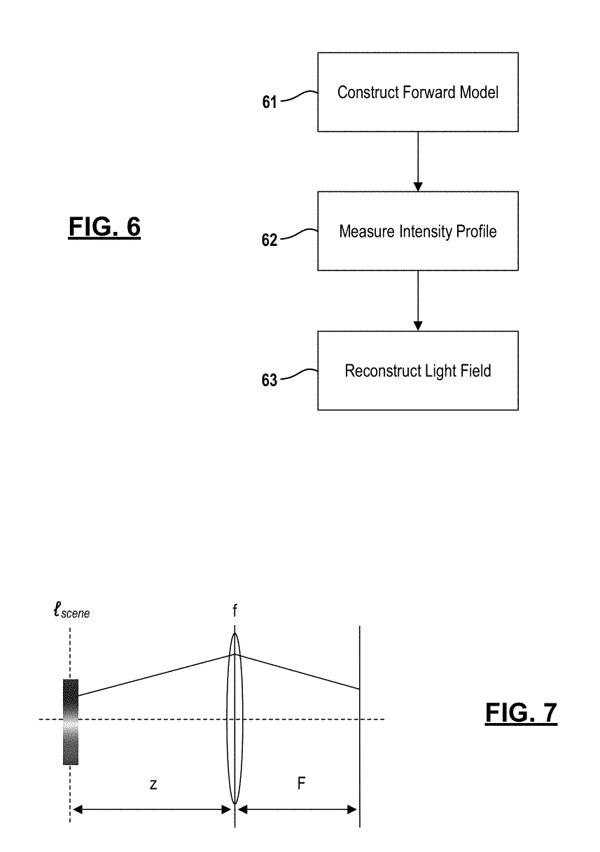

Next, a method is presented for reconstructing a light field from data recorded by the light field imaging system 10. Referring to FIG. 6, a forward model of the optical system is first constructed at 61. More specifically, the forward model describes the intensity profile measured in each plane of the focal stack in terms of the light field propagating through the system. In an example embodiment, the forward model includes a transformation matrix that relates a light field for any given scene to light intensity of rays from the scene as would be measured by a stack of detector planes in the light field imaging system. The measurement model may also consider additive noise or other noise models. To determine the transformation matrix, one can either use an experimental approach where the intensity profile for a known object or groups of objects (typically a point source) is measured by the light field imaging system, or one can compute the transformation matrix based on a mathematical model using ray tracing or more accurate optical transforms. The matrix may be stored explicitly as an array of numbers, or represented equivalently by computational functions that perform the operations of matrix-vector multiplication and the transpose thereof.

The reconstruction process then corresponds to an inversion of the forward model to determine the lightfield of an unknown object or scene. That is, light intensity profile for an unknown scene is measured at 62 by the light field imaging system. The light field for the unknown scene can be reconstructed at 63 using the measured light intensity profile and the forward model. In an example embodiment, the reconstruction is cast in the form of a least-squares minimization problem. The key subtlety in the solution is that there is a dimensionality gap: the light field is a 4D entity, while the focal stack array produces 3D of data. The proposed method accounts for this dimensionality gap as explained below.

For simplicity, an analysis is presented in a 2D space (2D lightfield). Consider a linear scene corresponding to a 1D object, with a reflectance pattern

$${𝓁}_{scene} = ( [ \begin{matrix}x \\ u\end{matrix} ] )$$

using plane-plane parameterization. The lightfield first travels a distance of z to a lens with focal length f and is then imaged onto a 1D sensor that is distance F behind the lens as seen in FIG. 7. It is straightforward to extend the result to 3D space (4D lightfield).

Next, consider the forward model. Under the paraxial approximation, the effect of lightfield propagation and imaging lens refraction can both be modeled in the form of

$${𝓁}^{′} ( [ \begin{matrix}x \\ u\end{matrix} ] ) = 𝓁 ( A [ \begin{matrix}x \\ u\end{matrix} ] ) ,$$

where A is the 2×2 optical transfer matrix. By the serial application of optical transfer matrices, the lightfield on the sensor is:

$${𝓁}_{sensor} ( [ \begin{matrix}x \\ u\end{matrix} ] ) = {𝓁}_{scene} ( {C}_{zfF} [ \begin{matrix}x \\ u\end{matrix} ] ) , where$$

$${C}_{zfF} = [ \begin{matrix}1 - \frac{z}{f} & zF ( \frac{1}{f} - \frac{1}{z} - \frac{1}{F} ) \\ \frac{1}{f} & 1 - \frac{F}{f}\end{matrix} ]$$

A camera coordinate re-parameterization is performed, making the x-axis be on the sensor (spatial axis) and the u-axis be on the lens (angular axis). The resulting lightfield in the camera now becomes

$${𝓁}_{sensor}^{cam} ( [ \begin{matrix}x \\ u\end{matrix} ] ) = {𝓁}_{scene} ( H [ \begin{matrix}x \\ u\end{matrix} ] ) , where H = [ \begin{matrix}- \frac{z}{F} & 1 - \frac{z}{f} - \frac{z}{F} \\ \frac{1}{F} & \frac{1}{f} - \frac{1}{F}\end{matrix} ]$$

The formulation can be directly generalized to the 3D space (4D lightfield) with planar scene object (2D):

$${𝓁}_{sensor}^{cam} ( [ \begin{matrix}x \\ u\end{matrix} ] , [ \begin{matrix}y \\ v\end{matrix} ] ) = {𝓁}_{scene} ( H [ \begin{matrix}x \\ u\end{matrix} ] , H [ \begin{matrix}y \\ v\end{matrix} ] ) ,$$

where H is defined as above and this can be rewritten in the form of simpler notations:

$${𝓁}_{sensor}^{cam} ( [ \begin{matrix}x \\ u\end{matrix} ] ) = {𝓁}_{scene} ( H [ \begin{matrix}x \\ u\end{matrix} ] )$$

where the bold characters

$$x = [ \begin{matrix}x \\ y\end{matrix} ] and u = [ \begin{matrix}u \\ v\end{matrix} ]$$

represent the 2D spatial and angular vector, respectively.

The image formation i(x) is the integration of [symbol] ₛₑₙₛₒᵣ^{cam}(x, u) over the aperture plane:

i(x)=∫ [symbol] ₛₑₙₛₒᵣ^{cam}(x, u)du

To track the computation, the lightfield is discretized as

$${𝓁}_{sensor}^{cam} ( x , u ) \approx {\sum }_{m} {\sum }_{p} {𝓁}_{sensor}^{cam} [ m , p ] \cdot {rect}_{{Δ}_{x}} ( x - m {Δ}_{x} ) {rect}_{{Δ}_{u}} ( u - p {Δ}_{u} )$$

where m and p are index vectors of dimension 2 that correspond to x and u, respectively, and the discrete image formation process now becomes

$$\begin{matrix}𝒾 [ m ] = \int ( \int {𝓁}_{sensor}^{cam} ( x , u ) du ) \cdot {rect}_{{Δ}_{x}} ( x - m {Δ}_{x} ) dx \\ = ( {𝓁}_{sensor}^{cam} * g ) [ m , 0 ] ,\end{matrix}$$

where g[m, p]=(s*t)(mΔₓ, pΔᵤ),

s(x, u)=rect_{Δ}_{ₓ}(x)rect_{Δ}_{ᵤ}(u) and t(x, u)=rect_{Δ}_{ₓ}(x)

It is directly seen that each discrete focal stack images can be computed in the linear closed form, hence the complete process of 3D focal stack formation from the 4D lightfield can be modeled by the linear operation of [symbol] =A· [symbol] +n, where A is the forward model, n is the detection noise, and [symbol] is the resulting measured focal stack.

The problem of reconstructing the scene lightfield from the focal stack data can then be posed as the least-square minimization problem of [symbol] =min [symbol] ∥ [symbol] −A· [symbol] ∥₂². While reference is made to least-squares minimization, other optimization techniques for solving this problem are also contemplated by this disclosure, such as those that include regularization.

There are two directions that are explored about such a camera system. First, through investigating the forward model A, the system is explicitly quantitatively evaluated with the design parameters such as number of detectors and the placement of them. Second, as the specific reconstruction is an ill-posed problem due to the dimensionality gap between 3D and 4D, a proper choice of regularization is required. With the qualitative study of reconstructed epipolar images on some simple scene, it is shown that a 4 dimensional total variation regularization can reduce the cross-epipolar interference and therefore further decreases the reconstruction error ∥ [symbol] _{recon}− [symbol] ₜᵣᵤₑ∥₂² and improves the visual quality of the image rendered from the reconstructed lightfield.

While the spatial relationship between photographs and lightfields can be understood intuitively, analyzing in the Fourier domain presents an even simpler view of the process of photographic imaging—a photograph is simply a 2D slice of the 4D light field. The proposed light-field imaging system is therefore analyzed in the Fourier domain. This is stated formally in the following Fourier slice photography theorem based on Lambertian scene and full aperture assumptions; the measurement at the dth detector is given by

$${𝒾}_{d} ( x , y ) = \frac{{γ}^{d - 1}}{{β}^{2}} {ℱ}_{2 D}^{- 1} \{ {S}_{d} \{ {ℱ}_{4 D} \{ 𝓁 ( x , y , u , v ) \} \} \} , d = 1 , … , D , \qquad ( 1 )$$

where [symbol] _{4D}{ [symbol] (x, y, u, v)}=L(fₓ, f_{y}, fᵤ, fᵥ) and [symbol] _{2D}{ [symbol] (x, y)}=L(fₓ, f_{y}) are the 4D and 2D Fourier transforms respectively and the slicing operator S_{d}{.} is defined by

S_{d}{F}(fₓ, f_{y}):=F(α_{d}fₓ, α_{d}f_{y},(1−α_{d})fₓ,(1−α_{d})f_{y}) (2)

{α_{d}β:α_{d} ∈ (0,1], d=1, . . . , D} denotes a set of distances between the lens and the dth detector, β is a distance between a lens and the furthest detector to the lens (i,e., the D-th detector with α_{D}=1), γ ∈ [0,1] is a transparency of the light detectors, fₓ, f_{y}, fᵤ, fᵥ ∈ [symbol] are frequencies and D is the number of detectors.

As noted above, the reconstruction problem of minimizing [symbol] =min [symbol] ∥ [symbol] −A· [symbol] ∥₂² is ill-posed and a proper regularization is sought that helps further decrease the reconstruction error ∥ [symbol] _{recon}− [symbol] ₜᵣᵤₑ∥₂². With the proposed scheme of the lightfield camera, now consider different scenarios of a planar scene object relative to the imaging system. One extreme case is that the object happens to be sharply imaged on one of the focal stack sheet (say the d-th detector). This is regarded as optimal detection, since the light from the object would disperse along the line in the frequency domain with slope α_{d}/(1−α_{d}) and be completely sampled by the d-th detector. The lightfield can be reconstructed with high quality using standard least-square minimization methods such as conjugate gradient (CG) descent even without any regularization. More commonly in normal operation, which is regarded as the typical case, the frequency-domain light distribution will fall somewhere between the sampling lines. In this case, minimizing the cost function without regularization would create artifacts on the images rendered from the reconstructed lightfield.

Because of the known “dimensionality gap” of 4D light field reconstruction from focal-stack sensor data, the ordinary least-squares approach will typically have multiple solutions. In such cases, the output of the CG algorithm can depend on the value used to initialize that iteration. To improve the quality of the reconstructed light field and to help ensure a unique solution to the minimization problem, it is often preferable to include a regularization term and use a regularized least-squares minimization approach, also known as a Bayesian method. In regularized least squares, one estimates the light field by [symbol] =argmin [symbol] ∥ [symbol] −A· [symbol] ∥₂²R( [symbol] ), where R denotes a regularization function. One simple choice of the regularizer is a 4D total variation (TV) approach that sums the absolute differences between neighboring pixels in the light field, where the “neighbors” can be defined between pixels in the same x-y or u-v planes, and/or in the same epipolar images defined as 2D slices in the x-u or y-v planes.

TV regularization is based on the implicit model that the light-field is piecewise smooth, meaning that its gradient (via finite differences) is approximately sparse. There are other more sophisticated sparsity models that are also suitable for 4D light field reconstruction. For example, one can use known light fields (or patches thereof) as training data to learn the atoms of a dictionary D for a sparse synthesis representation: [symbol] =Dz, where z denotes a vector of sparse coefficients. Alternatively, one could use training data to learn a sparsifying transform matrix W such that W [symbol] denotes a sparse vector of transform coefficients. Both of these sparsifying methods can be implemented in an adaptive formulation where one learns D or W simultaneously with the reconstruction without requiring training data. Other sparsity models such as convolutional dictionaries can be used to define the regularizer R. Typically the effect of such regularizers is to essentially reduce the number of degrees of freedom of the lightfield to enable 4D reconstruction from focal stack data.

The ability to reconstruct images with high fidelity will depend on having sufficient 3D data obtained from the focal stack; hence the image reconstruction quality will improve with a larger number of detector planes. This may be seen from the Fourier slice photography theorem, which suggests that the number of 4D Fourier samples of the light-field image x increases as the number of detectors D increases, yielding improvement of reconstruction quality with D. The optimal positions of the D detector planes is not necessarily with equal spacing along the z axis. In fact, an unequal spacing can be optimal, as seen in the following calculation. A direct consequence of the Fourier slice photography theorem is that the dth focal stack sheet will radially sample the vₓ−vᵤ and the v_{y}−vᵥ Fourier domains along a line with slope α_{d}/(1−α_{d}). Now consider a design of a lightfield camera of size β (distance between the last focal stack sheet and the imaging lens) for a working range between w₁ and w₂ (w₁>w₂) from the imaging lens. Point sources at w_{1,2} will be sharply imaged at α_{w}_{_{1,2}}β, which satisfies

$$\frac{1}{f} = \frac{1}{{w}_{1 , 2}} + \frac{1}{{α}_{{w}_{1 , 2}} β} .$$

These confine a sector between θ_{w}_{₁} and θ_{w}_{₂} in the vₓ−vᵤ and v_{y}−vᵥ domain, where

$${θ}_{{w}_{1}} = {tan}^{- 1} \frac{{α}_{{w}_{1}}}{1 - {α}_{{w}_{1}}} and {θ}_{{w}_{2}} = π + {tan}^{- 1} \frac{{α}_{{w}_{2}}}{1 - {α}_{{w}_{2}}} .$$

Without prior information about the scene (and therefore its 4D Fourier spectrum), one can arrange the N focal stack sheet locations such that they correspond to the radial sampling lines that have equal angular spacing by

$$δθ = \frac{{θ}_{{w}_{2}} - {θ}_{{w}_{1}}}{N}$$

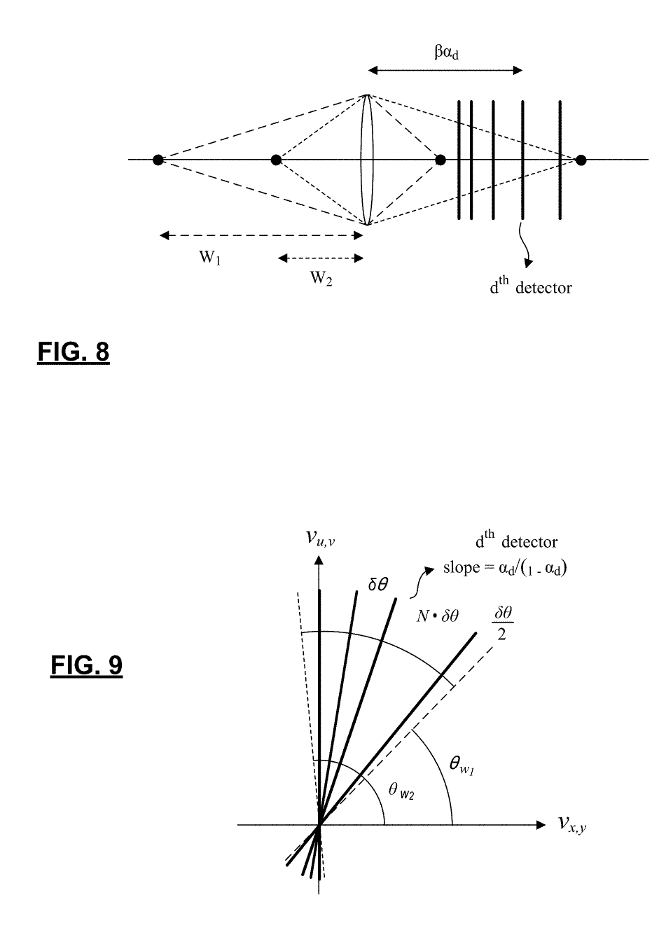

within the sector (confined by the designed working range) as seen in FIG. 8.

As illustrated in FIG. 9, such a configuration can be constructed in the following steps:

1. Numerically solve β from the constraint of

$$\frac{δθ}{2} = {θ}_{{w}_{2}} - \frac{π}{2}$$

in terms of w₁, w₂, f and N

2. Calculate θ_{w}_{₁}, θ_{w}_{₂} and δθ

3. Determine the position of the d-th focal stack sheet by

$${βα}_{d} = \frac{β tan [ ( {θ}_{{w}_{1}} + \frac{δθ}{2} ) + ( d - 1 ) δθ ]}{1 + tan [ ( {θ}_{{w}_{1}} + \frac{δθ}{2} ) + ( d - 1 ) δθ ]}$$

As a numerical example, if the lightfield camera is expected to work in the range of 30 cm to 3 m, the focal length of the imaging lens is 50 mm and has 5 transparent detectors, then the detector planes would be placed at [51.6, 53.3, 55.0, 56.9, 58.9] (mm) according to the above design guidelines. Note that the detector planes are unequally space along the optical axis. Nevertheless, this spacing will provide optimal sampling of the light field for a fixed number of detector planes and the working range (scene depth) in this design example. This numerical example is presented to describe one particular embodiment that has proven effective and should be viewed as illustrating, rather than limiting, the present disclosure.

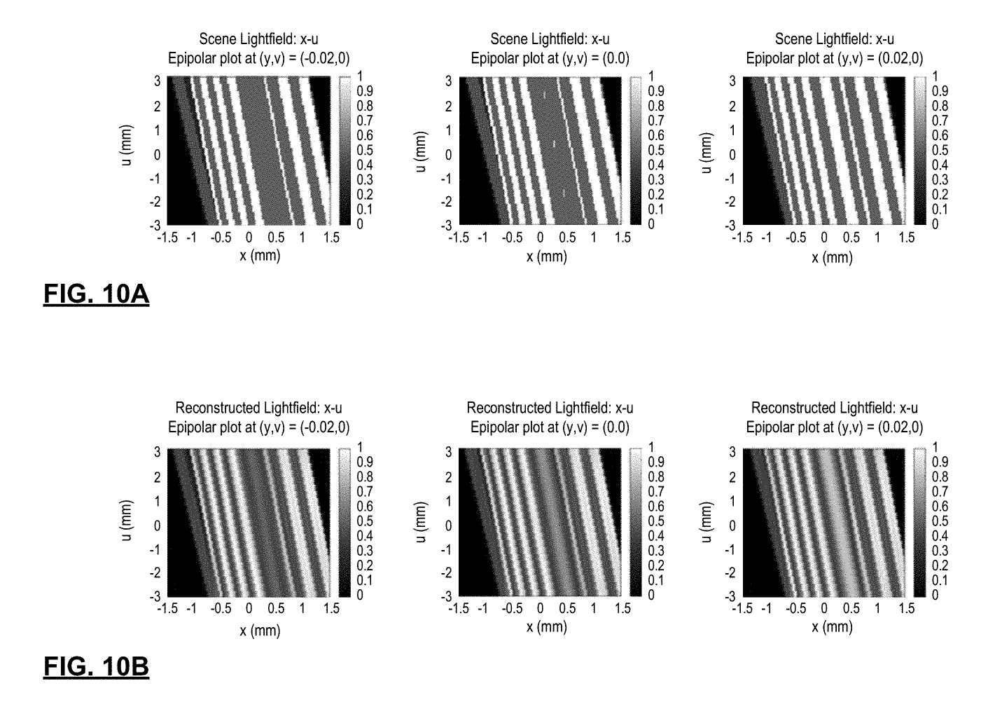

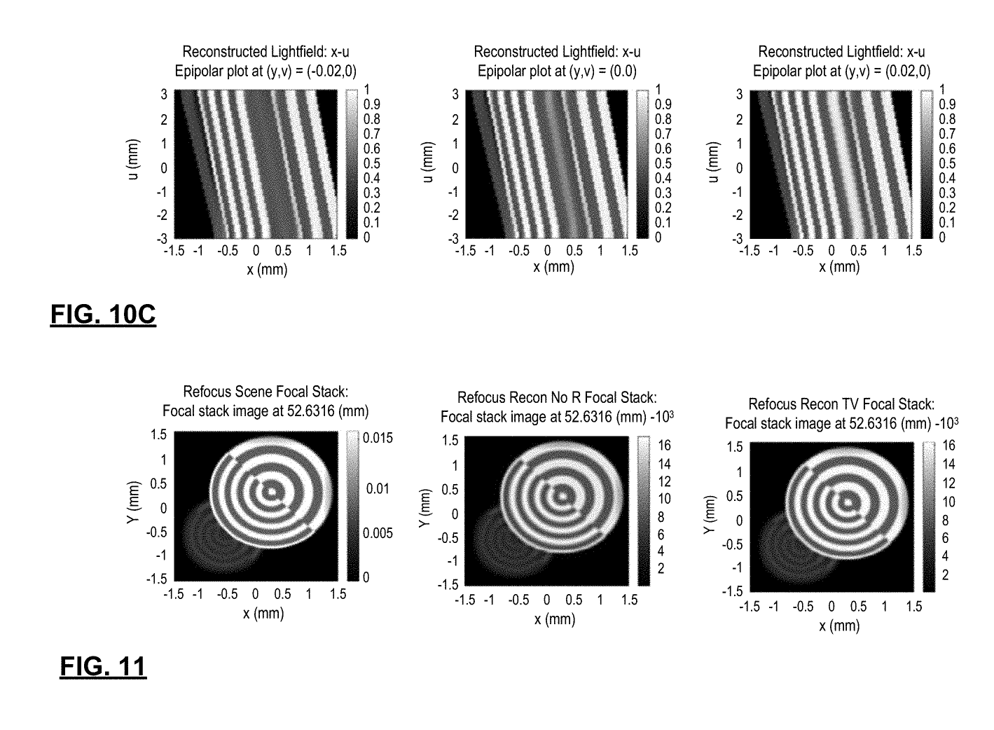

An example test of the normal case consists of two patterned disks at different depths, and the front disk transversely occludes part of the other. The lightfield camera is designed in accordance with the numerical example set forth above, and the two scene disks are placed accordingly as discussed below. Since lightfield is 4D data, it is challenging to visualize the data as a whole. One way to look at the lightfield data is through epipolar images, which are 2D slices of the 4D lightfield on either x−u or y−v directions. Due to the Lambertian/near-Lambertian nature of the scene, epipolar images usually consist of linear stripes with different slopes, in which the depth information is coded. First, one can minimize the cost function using conjugate gradient descent without regularization and then inspect the reconstructed epipolar images. The resulting images appear to be blurry, as can be seen in FIG. 10A. After examining a set of adjacent epipolar images, it is observed that they can exhibit cross-interference by the extended blur from the neighboring epipolar plots as seen in FIG. 10B. This suggest that the cross-epipolar, 4D total variation regularization should help improve the reconstruction as seen in FIG. 10C. The improvement in the epipolar domain directly leads to a distinctive improvement in the spatial image domain. In FIG. 11, the digitally refocused images rendered from the reconstructed lightfield are shown. As can be seen, the application of 4D TV greatly help reduced the artifacts between the ring pattern.

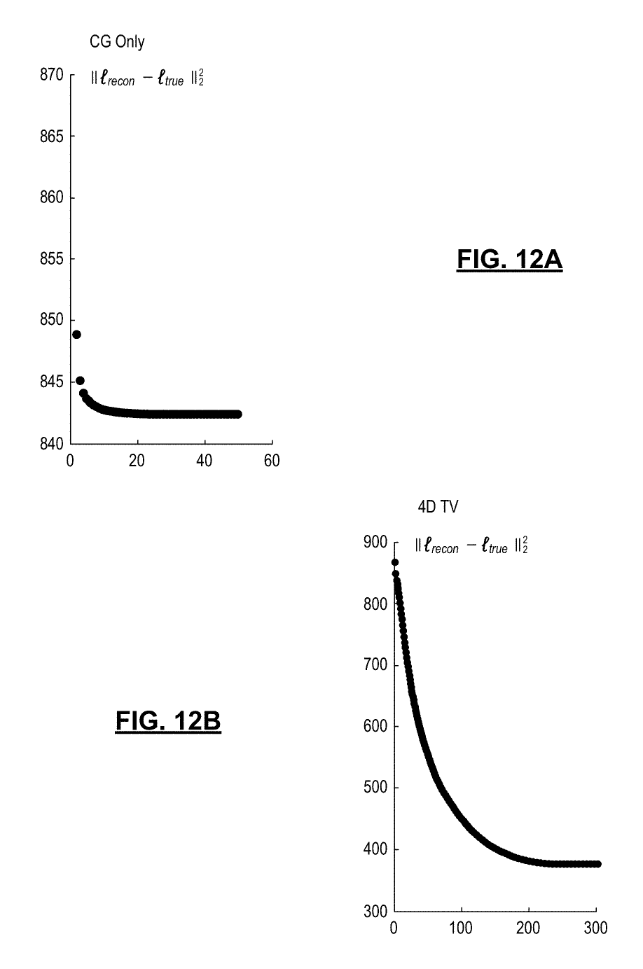

It is interesting to see how the 4D TV works with another extreme case, which can be considered as the baseline case, and can be generated as the following: place the planar object at w_{b}, which is sharply imaged at βα_{b} such that the spectral line with slope α_{b}/(1−α_{b}) would lie in the middle of the two spectral sampling lines imposed by the d-th and (d+1)-th detectors, i.e., θ_{w}_{_{b}}=θ_{w}_{₁}+d·δθ. As can be seen in FIGS. 12A and 12B, the application of 4D TV results is a significant improvement over CG without regularization, in terms of the mean square error ∥ [symbol] _{recon}− [symbol] ₜᵣᵤₑ∥₂².

Some portions of the above description present the techniques described herein in terms of algorithms and symbolic representations of operations on information. These algorithmic descriptions and representations are the means used by those skilled in the data processing arts to most effectively convey the substance of their work to others skilled in the art. These operations, while described functionally or logically, are understood to be implemented by computer programs. Furthermore, it has also proven convenient at times to refer to these arrangements of operations as modules or by functional names, without loss of generality.

Unless specifically stated otherwise as apparent from the above discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system memories or registers or other such information storage, transmission or display devices.

Certain aspects of the described techniques include process steps and instructions described herein in the form of an algorithm. It should be noted that the described process steps and instructions could be embodied in software, firmware or hardware, and when embodied in software, could be downloaded to reside on and be operated from different platforms used by real time network operating systems.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A light field imaging system, comprising:
a stack of two or more photodetectors having a planar shape; each of the two or more photodetectors is arranged in a different geometric plane and the geometric planes are substantially parallel with each other, wherein at least one of the photodetectors is transparent, such that the at least one transparent photodetector has transparency greater than fifty percent while simultaneously exhibiting responsivity greater than one amp per watt; and
an imaging optic configured to receive light rays from a scene and refract the light rays towards the stack of two or more photodetectors, such that the refracted light rays pass through the at least one transparent photodetector and the refracted light rays are focused within the stack of photodetectors.

2. The light field imaging system of claim 1 wherein the at least one transparent photodetectors includes a light absorbing layer on a substrate, where the light absorbing layer is comprised of a two-dimensional material and the substrate is comprised of a transparent material.

3. The light field imaging system of claim 1 wherein the at least one transparent photodetector has transparency greater than eighty-five percent.

4. The light field imaging system of claim 1 wherein the at least one transparent photodetector has responsivity greater than 100 amps per watt.

5. The light field imaging system of claim 1 wherein the imaging optic focuses the refracted light rays onto one of the two of more photodetectors.

6. The light field imaging system of claim 1 wherein the imaging optic focuses the refracted light rays in between two of the two or more photodetectors.

7. The light field imaging system of claim 1 wherein the imaging optic is further defined as an objective lens.

8. The light field imaging system of claim 1 further comprises an image processor in data communication with each of the photodetectors in the stack of two or more photodetectors and operates to reconstruct a light field for the scene using light intensity measured by each of the photodetectors.

9. A light field imaging system, comprising:
a stack of two or more detector planes, each of the two or more detector planes is arranged in a different geometric plane and the geometric planes are substantially parallel with each other,
each of the two or more detector planes includes an array of photodetectors and each photodetector includes a light absorbing layer and a substrate, wherein the light absorbing layer is comprised of a two-dimensional material and the substrate is comprised of a transparent material; and
an imaging optic configured to receive light rays from a scene and refract the light rays towards the stack of two or more detector planes, such that the refracted light rays pass through at least one of the detector planes and the refracted light rays are focused within the stack of two or more detectors planes.

10. The light field imaging system of claim 9 wherein each photodetector in an array of photodetectors aligns with a corresponding photodetector in each of the other arrays of photodetectors.

11. The light field imaging system of claim 1 wherein the two or more detector planes are spaced at unequal intervals.

12. The light field imaging system of claim 9 wherein the photodetectors have transparency greater than fifty percent while simultaneously exhibiting responsivity greater than one amp per watt.

13. The light field imaging system of claim 12 wherein the at least one transparent photodetector has transparency greater than eighty-five percent.

14. The light field imaging system of claim 12 wherein the at least one transparent photodetector has responsivity greater than 100 amps per watt.

15. The light field imaging system of claim 9 wherein the imaging optic focuses the refracted light rays onto one of the two of more photodetectors.

16. The light field imaging system of claim 9 wherein the imaging optic focuses the refracted light rays in between two of the two of more photodetectors.

17. The light field imaging system of claim 9 wherein the imaging optic is further defined as an objective lens.

18. The light field imaging system of claim 9 further comprises an image processor in data communication with each of the photodetectors in each detector plane in the stack of two or more photodetectors and operates to reconstruct a light field for the scene using light intensity measured by each of the photodetectors.

19. A method for reconstructing a light field from data recorded by a light field imaging system, comprising:
determining a transformation matrix that relates a light field to predicted light intensity of rays as measured by a stack of detector planes in the light field imaging system, each detector plane includes an array of photodetectors arranged in a different geometric plane and the geometric planes are substantially parallel with each other;
measuring light intensity of light propagating from an unknown scene at each detector plane in the stack of detector planes; and
reconstructing a light field for the unknown scene using the transformation matrix and the measured light intensity from the unknown scene.

20. The method of claim 19 wherein determining a transformation matrix further comprises measuring light intensity of light propagating from a set of known objects at each detector plane in the stack of detector planes.

21. The method of claim 19 further comprises determining the transformation matrix mathematically using ray tracing through the light field imaging system.

22. The method of claim 19 further comprises modeling image formation with a linear operation of f=A*l+n, where f denotes the measured light intensity from the stack of detector planes, A denotes the transformation matrix, l denotes the light field for the scene captured by the light field imaging system, and n denotes detection noise in the measured light intensity.

23. The method of claim 19 wherein reconstructing the light field further comprises solving a regularized least squares minimization problem.

24. The method of claim 23 wherein the regularization is based on total variation of the light field or based on a sparse representation of the light field.
